(19) United States
(12) Patent Application Publication
(10) Pub. No.: US 2008/0144857 A1
(43) Pub. Date: Jun. 19, 2008

(54) AUDIO SIGNAL OUTPUT CIRCUIT CAPABLE OF DECREASING POP NOISE

(76) Inventors: Shih-Hang Huang, Kao-Hsiung City (TW); Yu-Hu Yan, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/959,476

(22) Filed: Dec. 19, 2007

(30) Foreign Application Priority Data
Dec. 19, 2006 (TW) 095147687

(51) Int. Cl. H03B 29/00

(52) U.S. Cl. 381/94.5

(57) ABSTRACT

An audio signal output circuit capable of decreasing pop noise includes an acoustic output device for generating sound, an audio signal generating circuit coupled to the acoustic output device for outputting audio signals, and a noise reduction circuit coupled between the acoustic output device and the audio signal generating circuit for smoothing dc level variation of audio signals outputted from the audio signal generating circuit.

### BACKGROUND OF THE INVENTION

1. Field of the Invention

The present invention relates to an audio signal output circuit capable of decreasing pop noise and a related method, and more particularly, to an audio signal output circuit capable of decreasing pop noises caused by an acoustic output device when suddenly being charged or discharged.

2. Description of the Prior Art

In this multimedia filled life, sound quality becomes more and more important. Conventional audio signal output circuits, however, generate irritating ‘pop’ noises caused by circuit switching during outputting of audio signals.

Please refer to FIG. 1. FIG. 1 is a diagram illustrating a conventional audio signal output circuit 100. The audio signal output circuit 100 comprises an audio signal generating circuit 102, an amplifier 104, a resistor 106, and an acoustic output device 108. The audio signal generating circuit 102 comprises a voltage output circuit 110 and a signal generator 112. The voltage output circuit 110 outputs a bias voltage Vb. The signal generator 112 outputs a sinusoidal signal centered around 0 volts (with an amplifier of AB class) according to a sound source. The acoustic output device 108 can be realized by an earphone or other acoustic output circuit and the equivalent circuit of the acoustic output device 108 can be an equivalent capacitor 114 and an equivalent resistor 116. When the audio output circuit 100 outputs audio signals, the voltage output circuit 110 starts to output the bias voltage Vb so that the output sinusoidal signal of the signal generator 112 is biased around an appropriate voltage. When the audio signal output circuit 100 does not output audio signals, in order to save power, the voltage output circuit 110 will not output the bias voltage Vb.

The acoustic output device 108 operates regularly with the sinusoidal signal of the signal generator 112 properly biased around the voltage Vb. In order to save power, however, the voltage output circuit 110 outputs the bias voltage Vb only when the acoustic output device 108 outputs sound. Thus, the acoustic output device 108 generates pop noises because of the switching of the voltage output circuit 110. Please refer to FIG. 2. FIG. 2 is a diagram illustrating the condition when the audio signal output circuit 100 in FIG. 1 is turned on for outputting sound. When this occurs, the voltage output of the voltage output circuit 110 abruptly rises from 0 volts to the voltage Vb so that the equivalent capacitor 114 is suddenly charged, causing a current impulse +Ip into the acoustic output device 108 and generating the pop noise. Please refer to FIG. 3. FIG. 3 is a diagram illustrating the condition when the audio signal output circuit 100 is turned off to stop outputting sound. In this situation, the voltage output of the voltage output circuit 100 abruptly falls from the voltage Vb to 0 volts so that the equivalent capacitor 114 is suddenly discharged, causing a current impulse −Ip sinking from the acoustic output device 108 and the generating the pop noise once again.

In this way, the conventional audio signal output circuit 100 generates irritating pop noise when being turned on/off, thereby lowering the sound quality.

### SUMMARY OF THE INVENTION

The present invention provides an audio signal output circuit, capable of decreasing pop noise, comprising an acoustic output device for outputting sound; an audio signal generating circuit coupled to the acoustic output device for outputting audio signals; and a noise reduction circuit coupled between the audio signal generating circuit and the acoustic output device for smoothing dc level variation of audio signals outputted from the audio signal generating circuit.

The present invention further provides a method for decreasing noise with an audio signal output circuit. The audio signal output circuit comprises an acoustic output device for outputting sound, an audio signal generating circuit coupled to the acoustic output device for outputting audio signals, and a noise reduction circuit coupled between the audio signal generating circuit and the acoustic output device for smoothing dc level variation of audio signals outputted from the audio signal generating circuit. The method comprises utilizing the noise reduction circuit to sink current when the audio signal generating circuit is not activated; activating the inactivated audio signal generating circuit; utilizing the noise reduction circuit to gradually stop sinking current; and pulling up an output voltage of the acoustic output device gradually.

The present invention further provides a method for decreasing noise with an audio signal output circuit. The audio signal output circuit comprises an acoustic output device for outputting sound, an audio signal generating circuit coupled to the acoustic output device for outputting audio signals, and a noise reduction circuit coupled between the audio signal generating circuit and the acoustic output device for smoothing dc level variation of audio signals outputted from the audio signal generating circuit. The method comprises providing a equivalent resistance of the noise reduction circuit at a first predetermined value when the audio signal generating circuit is not activated; activating the inactivated audio signal generating circuit; gradually increasing the equivalent resistance of the noise reduction circuit from the first predetermined value to a second predetermined value; and pulling up an output voltage of the acoustic output device gradually.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a conventional audio signal output circuit 100.

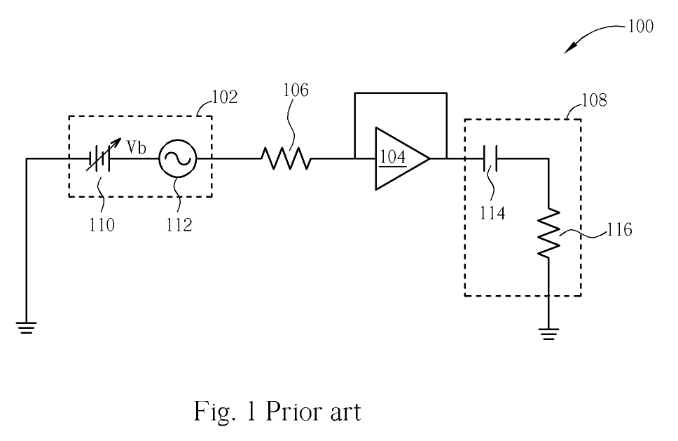

FIG. 2 is a diagram illustrating the condition when the audio signal output circuit 100 in FIG. 1 is turned on to output sound.

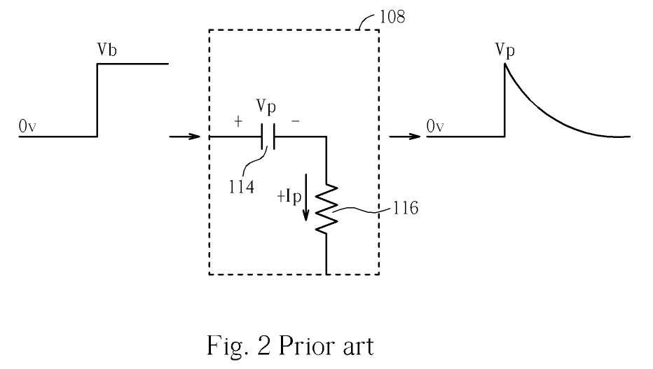

FIG. 3 is a diagram illustrating the condition when the audio signal output circuit 100 is turned off to stop outputting sound.

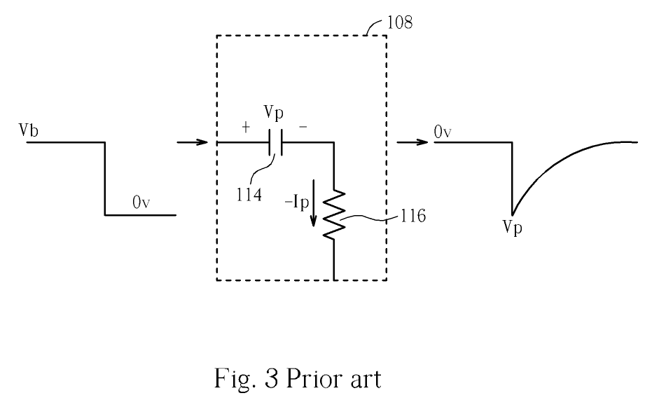

FIG. 4 is a diagram illustrating an audio signal output circuit 400 of an improved embodiment of the present invention.

FIG. 5 is a diagram illustrating the audio signal output circuit 400 being turned on to output sound.

FIG. 6 is a diagram illustrating the audio signal output circuit 400 being turned off to stop outputting sound.

### DETAILED DESCRIPTION

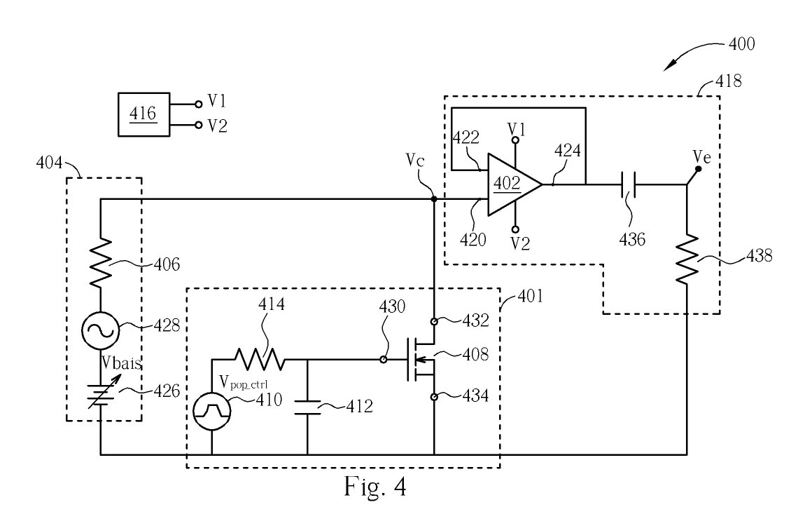

Please refer to FIG. 4. FIG. 4 is a diagram illustrating an audio signal output circuit 400 of an improved embodiment of the present invention. The audio signal output circuit 400 comprises a power supply circuit 416, an acoustic output device 418, an audio signal generating circuit 404, and a noise reduction circuit 401. The power supply circuit 416 outputs bias voltages V1 and V2. The acoustic output device 418 comprises a driving circuit and a loading circuit. The driving circuit comprises an amplifier 402. The loading circuit can be an earphone or other acoustic output circuit and the equivalent circuit of the loading circuit can be an equivalent capacitor 436 and an equivalent resistor 438. The amplifier 402 comprises a first input end 420, a second input end 422, and an output end 424. The output end 424 is coupled to the equivalent capacitor 436. The second input end 422 is coupled between the output end 424 and the equivalent capacitor 436. The audio signal generating circuit 404 comprises a voltage output circuit 426, a signal generator 428, and a first resistor 406. The voltage output circuit 426 outputs a bias voltage Vbias for biasing the sinusoidal signal output from the signal generator 428 around the voltage Vbias. The noise reduction circuit 401 comprises a transistor 408, a control signal generator 410, a capacitor 412, and a second resistor 414. The transistor 408 comprises a gate 430, a drain 432, and a source 434. The drain 432 is coupled to the first input end 420 of the amplifier 402. The source 434 is coupled to the ground end. In the present embodiment, the transistor 408 is an N-type metal oxygen semiconductor (NMOS) transistor. The control signal generating circuit 410 outputs a control signal Vpop_ctrl according to the status of the audio signal output circuit 400. The detailed description is as follows.

Those skilled in the art appreciate that when the voltage of the gate of the NMOS transistor falls from a high level, the impedance of the drain to the source of the NMOS transistor rises. The present invention utilizes such a characteristic with the transistor 408, the capacitor 412, and the second resistor 414 to avoid the pop noise occurring. In the default status, the audio signal generating circuit 404 is not turned on and the control signal Vpop_ctrl of the control signal generator 410 stays at a high level so that the transistor 408 is turned on by the high voltage of the gate 430 and the voltage Vc on the first input end 420 of the amplifier 402 is pulled down to the ground. In other words, the equivalent resistance of the noise reduction circuit 401 between the first input end 420 and the ground is 0 ohm. In such a condition, the output end 424 of the amplifier 402 remains at 0 volts despite the output signal of the audio signal generator 404. Thus the acoustic output device 418 does not output sound. When the audio signal output circuit 400 is turned on to output sound, the output voltage of the voltage output circuit 426 becomes the voltage Vbias. Meanwhile, the control signal Vpop_ctrl falls to a low level, which discharges the capacitor 412. In such a situation, the voltage of the gate 430 of the transistor 408 gradually falls and the impedance of the drain 432 to the source 434 rises. In other words, the equivalent resistance of the noise reduction circuit 401 between the first input end 420 and the ground gradually becomes infinity. Thus the voltage Vc of the first input end 420 of the amplifier 402 is gradually pulled up from the ground. Consequently, the voltage of the output end 424 of the amplifier 402 is gradually pulled up as well. Therefore, the acoustic output device 418 does not generate the pop noise because no current impulse is generated. On the other hand, when the audio signal output circuit 400 is turned off to stop outputting sound, the control signal Vpop_ctrl rises to the high level, which charges the capacitor 412. In such a situation, the voltage of the gate 430 of the transistor 408 gradually rises and the impedance of the drain 432 to the source 434 falls. Thus the voltage Vc of the first input end 420 of the amplifier 402 is gradually pulled down to the ground. Thus the equivalent capacitor 436 is gradually discharged which also avoids generating the pop noise.

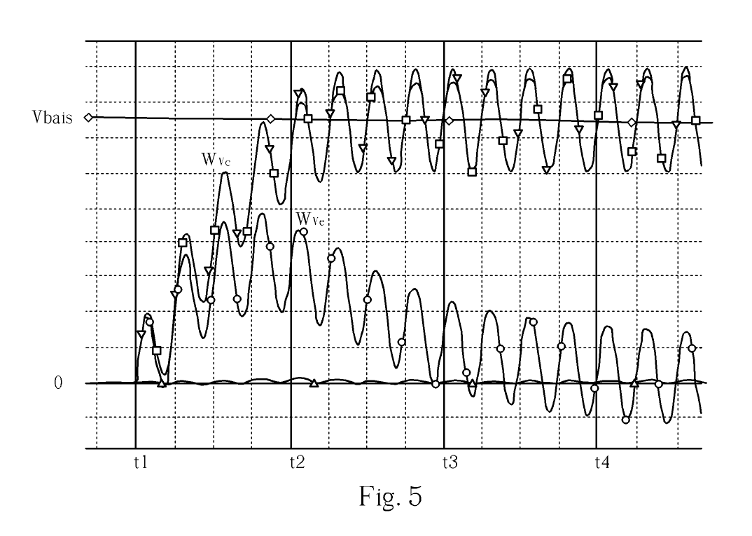

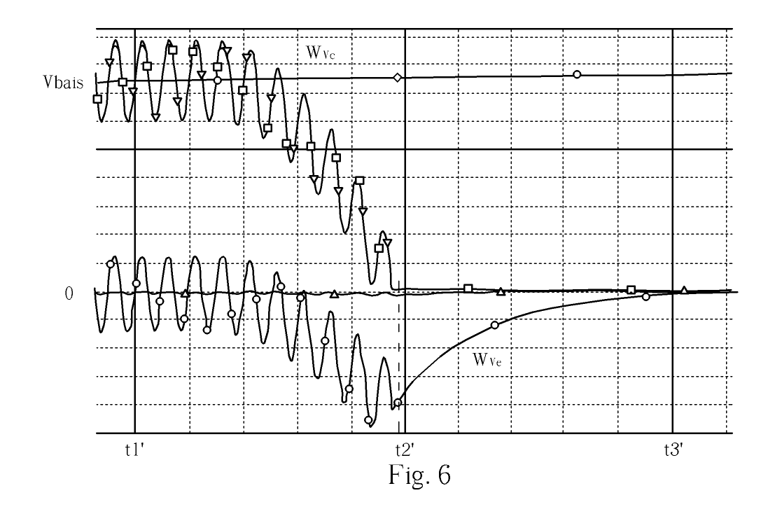

Please continue referring to FIG. 5 and FIG. 6. FIG. 5 is a diagram illustrating the audio signal output circuit 400 being turned on to output sound. FIG. 6 is a diagram illustrating the audio signal output circuit 400 being turned off to stop outputting sound. In FIG. 5 and FIG. 6, the waveforms Wvc and Wve respectively represent the voltage Vc of the first input end 420 of the amplifier 402 and the voltage Ve between the equivalent capacitor 436 and the equivalent resistor 438. As shown in FIG. 5, the audio signal output circuit 400 is turned on to output sound at time t1 and the dc level of the signal on the first input end rises to the voltage Vbias gradually instead of abruptly, which avoids generating the pop noise. As shown in FIG. 6, when the audio signal output circuit 400 is turned off to stop outputting sound at time t1′, the control signal Vpop_ctrl rises to the high level, and the dc level of the signal on the first input end falls to 0 gradually instead of abruptly, which also avoids generating the pop noise.

The present invention controls the transistor 408 with the control signal generator 410, capacitor 412, and the second resistor 414 to avoid suddenly charging or discharging the equivalent capacitor 436 so that the acoustic output device 418 does not generate the pop noise. Thus, the present invention not only saves power but also raises the sound quality, thereby providing significant benefits to users.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An audio signal output circuit capable of decreasing a pop noise comprising:
an acoustic output device for outputting sound;
an audio signal generating circuit coupled to the acoustic output device for outputting audio signals; and
a noise reduction circuit coupled between the audio signal generating circuit and the acoustic output device for smoothing dc level variation of audio signals outputted from the audio signal generating circuit.

2. The audio signal output circuit of claim 1 wherein the acoustic output device comprises:
a driving circuit coupled to the audio signal generating circuit for amplifying the audio signals output from the audio signal generating circuit; and
a loading circuit coupled to the driving circuit for converting signals output from the driving circuit into sound.

3. The audio signal output circuit of claim 2 wherein the driving circuit is an amplifier, and the amplifier comprises:
a first input end coupled to the audio signal generating circuit and the noise reduction circuit;
an output end coupled to the loading circuit; and
a second input end coupled between the output end and the loading circuit.

4. The audio signal output circuit of claim 1 wherein the audio signal generating circuit comprises a voltage output circuit and a signal generator.

5. The audio signal output circuit of claim 4 wherein the audio signal generating circuit further comprises a resistor coupled to the acoustic output device.

6. The audio signal output circuit of claim 1 wherein the noise reduction circuit comprises:
a switch comprising:
a first end,
a second end coupled between the acoustic output device and the audio signal generating circuit; and
a third end coupled to a ground end for coupling the ground to the second end with an adjustable impedance according to signals on the first end;
a control signal generating circuit for generating a control signal; and
a charging/discharging circuit coupled between the first end of the switch and the control signal generating circuit.

7. The audio signal output circuit of claim 6 wherein the switch is an N-type metal oxygen semiconductor transistor, the first end is a gate, the second end is a drain, and the third end is a source.

8. The audio signal output circuit of claim 6 wherein the charging/discharging circuit comprises:
a resistor coupled between the first end of the switch and the control signal generating circuit; and
a capacitor comprising:
a first end, coupled between the first end of the switch and the resistor; and
a second end coupled to the ground end.

9. The audio signal output circuit of claim 1 further comprising a power supply circuit for providing power.

10. A method for decreasing noise with an audio signal output circuit, the audio signal output circuit comprising an acoustic output device for outputting sound, an audio signal generating circuit coupled to the acoustic output device for outputting audio signals, and a noise reduction circuit coupled between the audio signal generating circuit and the acoustic output device for smoothing dc level variation of audio signals outputted from the audio signal generating circuit, the method comprising:
utilizing the noise reduction circuit to sink current when the audio signal generating circuit is not activated;
activating the inactivated audio signal generating circuit;
utilizing the noise reduction circuit to gradually stop sinking current; and
pulling up an output voltage of the acoustic output device gradually.

11. The method of claim 10 further comprising:
utilizing the noise reduction circuit to stop sinking current when the audio signal generating circuit is activated;
de-activating the activated audio signal generating circuit;
utilizing the noise reduction circuit to gradually sink current; and
pulling down the output voltage of the acoustic output device gradually.

12. A method for decreasing noise with an audio signal output circuit, the audio signal output circuit comprising an acoustic output device for outputting sound, an audio signal generating circuit coupled to the acoustic output device for outputting audio signals, and a noise reduction circuit coupled between the audio signal generating circuit and the acoustic output device for smoothing dc level variation of audio signals outputted from the audio signal generating circuit, the method comprising:
providing a equivalent resistance of the noise reduction circuit at a first predetermined value when the audio signal generating circuit is not activated;
activating the inactivated audio signal generating circuit;
gradually increasing the equivalent resistance of the noise reduction circuit from the first predetermined value to a second predetermined value; and
pulling up an output voltage of the acoustic output device gradually.

13. The method of claim 12 further comprising:
providing the equivalent resistance of the noise reduction circuit at the second predetermined value when the audio signal generating circuit is activated;
de-activating the activated audio signal generating circuit;
gradually decreasing the equivalent resistance of the noise reduction circuit from the second predetermined value to the first predetermined value; and
pulling down the output voltage of the acoustic output device gradually.

14. The method of claim 11 wherein the first predetermined value is 0 and the second predetermined value is infinity.
